(19) United States
(12) Patent Application Publication
(10) Pub. No.: US 2026/0239646 A1
(43) Pub. Date: Aug. 13, 2026

(54) SELF-ALIGNED PROCESS FOR SILICON CARBIDE TRENCH MOSFET

(71) Applicant: Renesas Electronics Corporation, Tokyo (JP)

(72) Inventors: Kijeong HAN, Morrisville, NC (US); Meng Chia LEE, Dallas, TX (US)

(73) Assignee: Renesas Electronics Corporation, Tokyo (JP)

(21) Appl. No.: 19/050,467

(22) Filed: Feb. 11, 2025

(51) Int. Cl. H10D 30/01; H10D 30/66; H10D 62/10

(52) U.S. Cl. CPC H10D 30/0297; H10D 30/668; H10D 62/105

(57) ABSTRACT

A method of forming a semiconductor structure includes forming a first insulating layer extending above an upper surface of a doped region and an upper surface of a source region positioned above a drift layer on a silicon carbide substrate. A trench feature penetrates the first insulating layer to reach an upper surface of the drift layer. A gate oxide is formed within the trench feature lining the bottom and sidewalls of the trench. A gate electrode is formed within the trench feature, with a first portion extending vertically above the trench feature and a second portion filling the trench feature. The first insulating layer is selectively removed, and a second insulating layer is formed around the first portion of the gate electrode. The second insulating layer extends partially above the upper surface of the source region and has a dome-like shape.

### BACKGROUND

The present disclosure generally relates to the field of semiconductor devices, and more particularly to trench silicon carbide metal-oxide-semiconductor field-effect transistors.

Silicon carbide (SiC) trench metal-oxide-semiconductor field-effect transistors (MOSFETs) are a critical advancement in power electronics due to their superior performance in high-voltage and high-temperature environments compared to traditional silicon-based devices. SiC possesses wide bandgap properties, which enable higher breakdown voltages, greater thermal conductivity, and improved efficiency in power conversion applications. Trench MOSFETs, in particular, offer the advantages of reduced on-resistance and enhanced current handling capabilities, making them well-suited for use in electric vehicles, renewable energy systems, industrial motor drives, and power supply units.

The design of SiC trench MOSFETs involves incorporating a trench structure into the gate region to optimize the distribution of the electric field, thereby minimizing the on-resistance and improving device efficiency. This structure also facilitates better scalability for higher voltage ratings and lower losses during switching operations, which is essential for improving the overall efficiency of power systems. However, the manufacturing process for SiC trench MOSFETs presents challenges, particularly in terms of material quality, process uniformity, and device reliability under harsh operating conditions.

### SUMMARY

According to an embodiment of the present disclosure, a method of forming a semiconductor structure includes forming a first insulating layer extending above an upper surface of a doped region and an upper surface of a source region positioned above a drift layer on a semiconductor substrate, the semiconductor substrate including a silicon carbide substrate, forming a trench feature within the first insulating layer, the trench feature penetrating the first insulating layer to reach an upper surface of the drift layer, forming a gate oxide within the trench feature, the gate oxide lining a bottom surface and opposite sidewalls of the trench feature, forming a gate electrode within the trench feature, a first portion of the gate electrode extending vertically above the trench feature, a second portion of the gate electrode filling the trench feature, selectively removing the first insulating layer from the semiconductor structure, and forming a second insulating layer surrounding the first portion of the gate electrode, the second insulating layer extending partially above the upper surface of the source region, with the second insulating layer having a dome-like shape.

According to another embodiment of the present disclosure, a method of forming a semiconductor structure includes forming a drift layer above a semiconductor substrate, the drift layer and the semiconductor substrate including a first conductivity type, the semiconductor substrate including a silicon carbide substrate, forming a base region of a second conductivity type above the drift layer, the base region providing a channel region for the semiconductor structure, forming a source region of the first conductivity type above the base region, forming a doped region of the second conductivity type adjacent to the base region and the source region, forming a first insulating layer above the doped region and the source region, forming a trench feature within the first insulating layer, the trench feature penetrating the first insulating layer to reach an upper surface of the drift layer, forming a gate oxide within the trench feature, the gate oxide lining a bottom surface and opposite sidewalls of the trench feature, forming a gate electrode within the trench feature, a first portion of the gate electrode extending vertically above the trench feature, a second portion of the gate electrode filling the trench feature, selectively removing the first insulating layer from the semiconductor structure, and forming sidewall spacers on opposite sides of the first portion of the gate electrode, wherein a portion of a spacer material forming the sidewall spacers remains above the first portion of the gate electrode providing a dome-like shape, the sidewall spacers extending partially above the upper surface of the source region.

According to another embodiment of the present disclosure, a semiconductor structure includes a drift layer disposed above a semiconductor substrate, the drift layer and the semiconductor substrate including a first conductivity type, with the semiconductor substrate including a silicon carbide substrate, a gate electrode within a trench feature positioned above the drift layer, the gate electrode including a first portion and a second portion, wherein the first portion of the gate electrode extends above the trench feature and the second portion of the gate electrode fills the trench feature, a source region of the first conductivity type adjacent to the second portion of the gate electrode, a doped region of a second conductivity type adjacent to the source region, with an upper surface of the doped region being coplanar with an upper surface of the source region, and an insulating layer surrounding the first portion of the gate electrode, the insulating layer partially covering the upper surface of the source region, the insulating layer including a dome-like shape.

### BRIEF DESCRIPTION OF THE DRAWINGS

The following detailed description, given by way of example and not intended to limit the embodiments described herein, will best be appreciated in conjunction with the accompanying drawings, in which:

FIG. 1 is a cross-sectional view of a semiconductor structure at an intermediate step during a semiconductor fabrication process, according to an embodiment of the present disclosure;

FIG. 2 is a cross-sectional view of the semiconductor structure depicting forming an oxide layer within a trench, according to an embodiment of the present disclosure.

FIG. 3 is a cross-sectional view of the semiconductor structure depicting forming a gate electrode, according to an embodiment of the present disclosure;

FIG. 4 is a cross-sectional view of the semiconductor structure after conducting an etching process on the gate electrode, according to an embodiment of the present disclosure;

FIG. 5 is a cross-sectional view of the semiconductor structure after selectively removing a first insulating layer, according to an embodiment of the present disclosure;

FIG. 6 is a cross-sectional view of the semiconductor structure after forming a second insulating layer above upper surfaces of the gate electrode, source regions, and doped regions, according to an embodiment of the present disclosure;

FIG. 7 is a cross-sectional view of the semiconductor structure after etching the second insulating layer, according to an embodiment of the present disclosure;

FIG. 8 is a cross-sectional view of the semiconductor structure after forming a top metal layer, according to an embodiment of the present disclosure; and

FIG. 9 is a flowchart depicting operational steps for the fabrication of the semiconductor structure, according to an embodiment of the present disclosure.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that may be ordinary in the art may have been combined together for presentation and for illustration purposes and in some instances may have not been described in detail. In other instances, some processing steps or operations that may be ordinary in the art may not be described at all. It should be understood that the following description is rather focused on the distinctive features or elements of various embodiments of the present disclosure.

In SiC MOSFETs, the channel density plays a crucial role in reducing overall resistance, which is particularly important due to the material's low channel mobility and high interface trap density. To address this, efforts are made to reduce the cell pitch to increase channel density, improving device performance. In SiC trench MOSFETs, a recessed poly-silicon (Poly-Si) gate structure is commonly used to reduce the cell pitch, allowing for higher channel density. However, this design introduces several challenges in the fabrication process, particularly with two key difficulties that affect the overall performance and manufacturability of the devices.

The first challenge arises from the source-to-gate space dimension. In the recessed Poly-Si gate structure, the self-aligned process, which is typically used to accurately position the gate relative to the source, cannot be applied. As a result, the space between the source and gate must be defined by the mask, leaving limited flexibility in the design. This misalignment leads to the need for a sufficient margin to ensure proper device operation, which in turn limits the ability to reduce cell pitch effectively.

The second issue concerns the vertical overlap margin between the Poly-Si gate and the N+ region. To ensure that the MOSFET turns on correctly, the P region must be fully overlapped with the Poly-Si gate to form the inversion channel. Achieving this overlap requires the N+ region to be deep enough for proper contact, which results in the need for a larger vertical overlap margin. This increased margin leads to deeper trench formations and higher implant energies, making the manufacturing process more complex and costly. These challenges present significant obstacles in improving the efficiency and reducing the cost of SiC trench MOSFETs.

Therefore, embodiments of the present disclosure address the challenges of the recessed Poly-Si gate structure by utilizing a self-aligned intermetal dielectric (IMD) process that allows the Poly-Si gate to protrude above the SiC surface. In this self-aligned fabrication process, typical misalignment concerns are substantially decreased, allowing for a more aggressive design of the source-to-gate space (W_{G-S} space), which can be optimized to reduce the cell pitch without compromising device performance.

Embodiments of the present disclosure include a semiconductor fabrication process that uses a SiN hard mask for protecting the SiC surface during the sidewall treatment after trench etching. In conventional processes, sidewall treatment is necessary to remove etching damage, but it often consumes the top SiC surface, which can affect the N+region junction depth. By using the SiN hard mask, the top SiC surface remains unaffected during the process, allowing for greater precision and preserving the integrity of the SiC surface.

Furthermore, the proposed semiconductor fabrication process may eliminate the need for Poly-Si recess etching, meaning that recess etching margins may no longer be a concern. This allows the N+ region junction depth to be kept shallow, which reduces the trench depth and the required implant energy. As a result, the overall process becomes more efficient, with lower costs, while still achieving the performance benefits of reduced cell pitch and higher channel density.

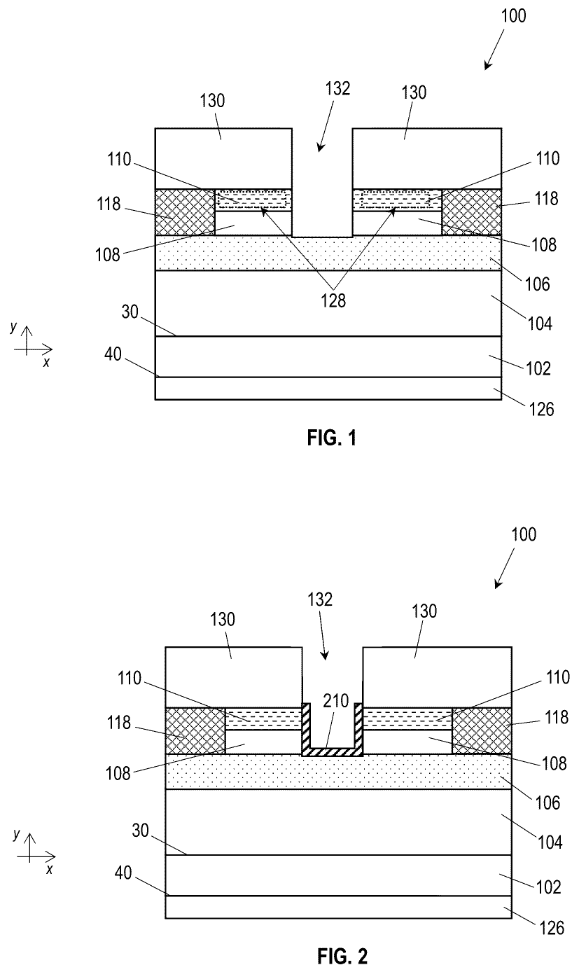

Embodiments by which the SiC trench MOSFET with self-aligned process can be formed is described in detail below by referring to the accompanying drawings in FIGS. 1-9.

FIG. 1 is a cross-sectional view of a semiconductor structure 100 at an intermediate step during a semiconductor fabrication process, according to an embodiment of the present disclosure. In this embodiment, semiconductor structure 100 is a SiC trench MOSFET structure.

As depicted in the figure, semiconductor structure 100 can include a semiconductor substrate (hereinafter “substrate”) 102 of a first conductivity type that is made of silicon carbide (SiC). A thickness of the initial substrate 102 can be approximately 350 μm. The substrate 102 can be grinded to approximately 100 mm during backside processing steps. The impurity concentration in the substrate 102 can vary between approximately 1×10¹⁸ cm⁻³ to approximately 1×10¹⁹ cm⁻³. The first conductivity type can be P-type or N-type. In the depicted embodiment, the first conductivity type is N-type.

It should be noted that substrate 102 serves as a drain region for the semiconductor structure 100, providing a pathway for current flow. While the drain region is integrated within the substrate 102, in some embodiments it can be engineered with distinct doping characteristics or other modifications to meet specific designs, enhance performance or manage thermal properties. Substrate 102 further includes an upper surface 30 and a bottom surface 40.

A bottom metal layer 126 can be formed on the bottom surface 40 of the substrate 102. The bottom metal layer 126 serves as a drain terminal or drain electrode that provides electrical (ohmic) contact with substrate 102.

A drift layer 104 of the first conductivity type can be formed on the upper surface 30 of the substrate 102. The drift layer 104 is made of silicon carbide with an added impurity concentration that is lower than the impurity concentration of substrate 102. Drift layer 104 can be a region where carriers (e.g., electrons or holes) can drift from source region 110 to drain region or substrate 102. In general, drift layer 104 can be formed by epitaxial growth by using the semiconductor substrate 102 as seed layer. Terms such as “epitaxial growth and/or deposition” and “epitaxially formed and/or grown” refer to the growth of a semiconductor material on a deposition surface of a semiconductor material, in which the semiconductor material being grown has the same or substantially similar crystalline characteristics as the semiconductor material of the deposition surface. In some embodiments, drift layer 104 can be formed by chemical vapor deposition (CVD) of the semiconductor material (i.e., SiC).

A thickness of the drift layer 104 can be determined by the device voltage rating. For example, the thickness of the drift layer 104 can be approximately 10 μm for 1.2 kV rated devices. The impurity concentration of the drift layer 104 can be approximately 1×10¹⁶ cm⁻³ for 1.2 kV rated devices. However, the impurity concentration of the drift layer 104 is not limited to this value and may be in a range of approximately 1×10¹⁴ cm⁻³ to approximately 1×10¹⁷ cm⁻³ depending on the device voltage rating.

A junction field-effect transistor (JFET) region 106 can be formed above and in contact with the drift layer 104. In some instances, JFET region 106 can be formed with a higher donor doping of the first conductivity type that can vary between approximately 1×10¹⁵ cm⁻³ and approximately 1×10¹⁸ cm⁻³. A thickness of the JFET region 106 can be approximately 0.1 μm to approximately 3.5 μm.

A base region 108, including a doped semiconductor region of a second conductivity type, can be formed above and in contact with the JFET region 106. A thickness of the base region 108 can be approximately 0. 1μm to approximately 1.0 μm. The impurity concentration of the base region 108 can vary between approximately 1×10¹⁹ cm⁻³ to approximately 1×10²¹ cm⁻³. The second conductivity type can be P-type or N-type. Generally, the second conductivity type is opposite to the first conductivity type. Thus, in the depicted embodiment, the second conductivity type is P-type. In an embodiment, a channel region 128 of the second conductivity type is formed within base region 108. Channel region 128 is in contact with JFET region 106 and adjacent to source region 110 and doped region 118. Channel region 128 is essentially a conducting path formed in the base region 108, where carriers can flow between source region 110 and substrate 102 (i.e., the drain region), enabling the MOSFET's switching function.

Source region 110 can be formed above and in contact with base region 108. A thickness of the source region 110 is approximately 0.1 μm to approximately 0.5 μm. Source region 110 may include a heavily-doped semiconductor layer of the first conductivity type. A dopant concentration of source region 110 can vary, for example, between 1×10¹⁹ cm⁻³ and 1×10²¹ cm⁻³.

In one or more embodiments, varying impurity or dopant concentrations across the different regions of semiconductor structure 100 can be attained through ion implantation or the diffusion of impurity ions or dopants. For example, in embodiments in which the first conductivity type is N-type and the second conductivity type is P-type, N-type dopants such as phosphorus (P) or arsenic (As) can be implanted into different regions of semiconductor structure 100 to form N-type doped semiconductor regions, while P-type dopants such as boron (B), aluminum (Al) or gallium (Ga) can be implanted into different regions of semiconductor structure 100 to form the P-type doped semiconductor layers.

With continued reference to FIG. 1, doped region 118 can be formed above and in contact with JFET region 106 and adjacent to base region 108 and source region 110. Doped region 118 includes a semiconductor region composed of a heavily doped silicon carbide layer of the second conductivity type. An ion implantation process can be conducted on the semiconductor structure 100 to form doped region 118. Doped region 118 can be formed with an impurity concentration of the second conductivity type varying between approximately 1×10¹⁹ cm⁻³ and approximately 1×10²¹ cm⁻³. In embodiments in which the second conductivity type is P-type, doped region 118 can be referred to as P+ region. A thickness of doped region 118 can vary between approximately 0.1 μm and approximately 3.5 μm. In one or more embodiments, doped region 118 may allow for the separation of P+ and N+ contacts which can increase P+ contact area and minimize the risk of N-P-N latch-up during UIS and short-circuit tests.

With continued reference to FIG. 1, a first insulating layer 130 is formed above an upper surface of the semiconductor structure 100. Specifically, the first insulating layer 130 is deposited over and in contact with upper surfaces of the doped region 118 and the source region 110. The first insulating layer 130 serves as a hard mask to protect underlying layers of the semiconductor structure 100 during a subsequent etching process. In this embodiment, the first insulating layer 130 is made of silicon nitride (SiN), although other materials with similar properties may also be used. The first insulating layer 130 can be deposited using any suitable deposition technique, such as CVD. A thickness of the first insulating layer 130 is dependent on the trench depth and typically ranges from approximately 1 μm to approximately 10 μm. In the depicted embodiment, a depth of trench 132 may be approximately 0.1 μm to approximately 5.0 μm. In general, a deeper trench 132 may require a thicker first insulating layer 130.

After the first insulating layer 130 is formed, a photoresist layer (not shown) can be applied and patterned using photolithography to define a trench geometry. The patterned photoresist acts as a mask for etching the first insulating layer 130. In an embodiment, reactive ion etching (RIE) or similar dry etching techniques can be used to etch through the first insulating layer 130 and expose underlying SiC layers. More particularly, etching the first insulating layer 130 exposes a top surface of source region 110. Once first insulating layer 130 is patterned, the exposed SiC areas (i.e., source region 110, base region 108 and a top surface of the JFET region 106) are etched to form a trench feature (hereinafter “trench”) 132 using a selective etching process, such as a chlorine-or fluorine-based etching chemistry. This process may allow forming the trench 132 with controlled depth and dimensions.

After forming the trench 132, the first insulating layer 130 remains in place to protect the surrounding regions during subsequent processing. Specifically, during sidewall treatment which is typically performed after trench etching to remove any etching damage to the trench sidewalls. During this process, top SiC surfaces can also be consumed, making the depth of the N+ region junction an important consideration in trench MOSFET processes, particularly when a recessed poly-Si gate is used. However, in the proposed embodiment, the top SiC surface is protected by the first insulating layer 130 during post-trench sidewall treatment, ensuring that the surface remains unaffected by the trench sidewall treatment. Absence of the first insulating layer 130 during post-trench cleaning, may expose upper SiC surfaces to aggressive cleaning chemicals, potentially leading to surface roughening, unintended oxidation, or contamination. This may compromise the integrity of the trench 132 and surrounding areas, which may negatively affect MOSFET performance.

FIG. 2 is a cross-sectional view of the semiconductor structure 100 depicting forming an oxide layer 210 within trench 132, according to an embodiment of the present disclosure. It should be noted that the description of FIG. 2 can refer to components shown in FIG. 1.

In the depicted embodiment, oxide layer 210 is formed within trench 132, typically using a thermal oxidation process or CVD to grow or deposit a thin layer of oxide on the trench sidewalls. The oxide layer 210 within the trench 132 serves as the gate dielectric or gate oxide for the semiconductor structure 100. The oxide layer 210 can electrically separate a subsequently formed gate electrode 340 from active areas of the semiconductor structure 100. A first portion of the oxide layer 210 parallel to substrate 102 is disposed above and in contact with JFET region 106, while second portions of the oxide layer 210 perpendicular to the substrate 102 are disposed in contact with sidewalls of the source region 110 and base region 108 located on opposite sides of the trench 132. It should be noted that oxide layer 210 may form on exposed SiC surfaces but not on the (SiN) first insulating layer 130 due to the selectivity of the oxidation or deposition process.

Non-limiting examples of gate insulating films to form oxide layer 210 may include silicon dioxide (SiO₂), silicon nitride (Si₃N₄), aluminum oxide (Al₂O₃), lanthanum oxide (La₂O₃), zirconium dioxide (ZrO₂), tantalum oxide (Ta₂O₅), hafnium oxide (HfO₂) and the like. In an exemplary embodiment, a thickness of the oxide layer 210 can vary between approximately 10 nm to approximately 100 nm. It should be noted that first insulating layer 130 remains in the semiconductor structure 100 during this step, shielding SiC surfaces outside the trench 132 from oxidation.

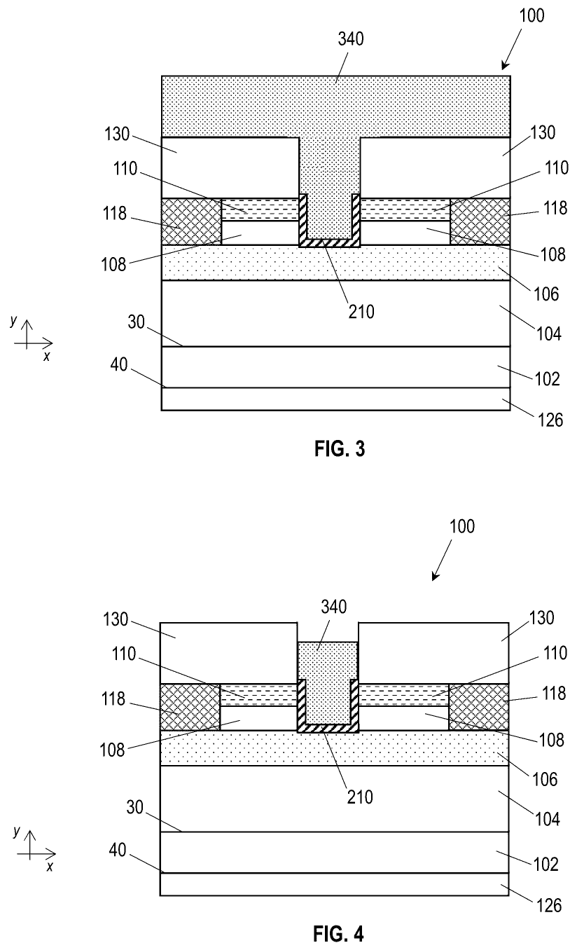

FIG. 3 is a cross-sectional view of the semiconductor structure 100 depicting forming a gate electrode 340, according to an embodiment of the present disclosure. It should be noted that the description of FIG. 3 can refer to components shown in FIG. 1, and FIG. 2.

To form the gate electrode 340, a layer of conductive material, such as polysilicon, is deposited within the trench 132 (FIG. 2). The conductive material is deposited directly on top of the oxide layer 210 that lines the trench 132. The deposition process can be controlled such that the conductive material substantially fills the trench 132, extending above the first insulating layer 130. This results in the formation of the gate electrode 340, with the oxide layer 210 functioning as the gate dielectric. The gate electrode 340, in combination with the oxide layer 210, defines the gate structure of the semiconductor structure 100. After forming the gate electrode 340, an etching process can be conducted on the semiconductor structure 100, as will be described in detail below.

FIG. 4 is a cross-sectional view of the semiconductor structure 100 after conducting an etching process on the gate electrode 340, according to an embodiment of the present disclosure. It should be noted that the description of FIG. 4 can refer to components shown in FIG. 1, FIG. 2, and FIG. 3.

Following the deposition of the gate electrode 340, an etching process can be conducted on the semiconductor structure 100 to selectively remove portions of the (polysilicon) gate electrode 340 extending above uppermost surfaces of the (SiN) first insulating layer 130. The etching process can be controlled to ensure that the conductive material forming the gate electrode 340 is etched away from horizontal surfaces (i.e., surfaces parallel to the substrate 102), while preserving portions of the gate electrode 340 in contact with vertical sidewalls of the first insulating layer 130. In an embodiment, a dry etching process, such as RIE, may be used for this step due to its ability to etch polysilicon while maintaining the integrity of the underlying SiN first insulating layer 130. The selective etching may ensure that the first insulating layer 130 remains in the semiconductor structure 100, serving as an etch stop and protecting sidewall areas of the trench 132. After the polysilicon etch-back, a remaining portion of conductive material within trench 132 forms a well-defined gate electrode 340 that is aligned with the sidewalls of the first insulating layer 130.

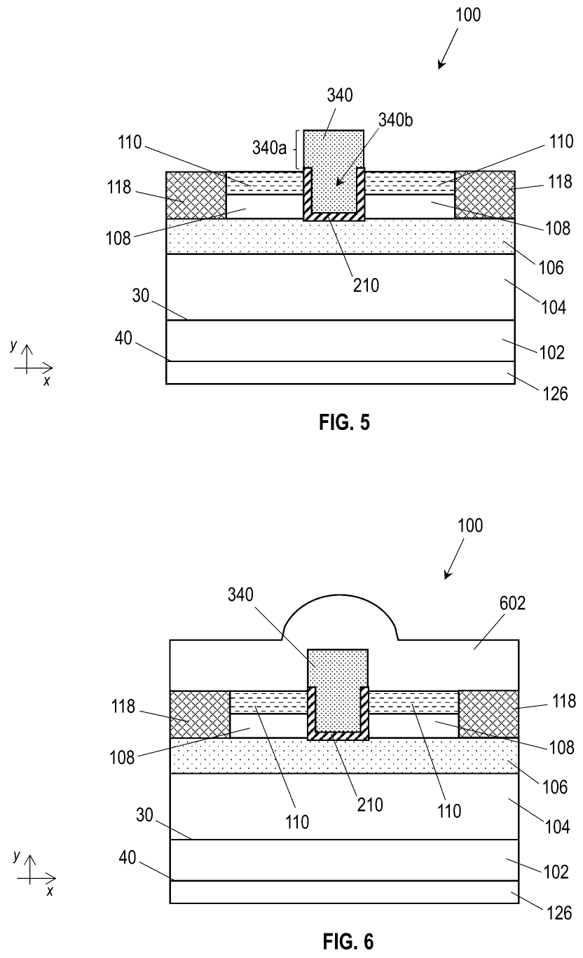

FIG. 5 is a cross-sectional view of the semiconductor structure 100 after selectively removing the first insulating layer 130, according to an embodiment of the present disclosure. It should be noted that the description of FIG. 5 can refer to components shown in FIG. 1, FIG. 2, FIG. 3, and FIG. 4.

After etching the gate electrode 340, the first insulating layer 130 can be removed. In this embodiment, removal of the first insulating layer 130 can be achieved through a selective etching process that targets the (SiN) first insulating layer 130 while leaving the underlying structures, including the gate electrode 340, the oxide layer 210, and SiC regions (e.g., source regions 110 and doped regions 118), unaffected. For example, a RIE process using a fluorine-based etchant, such as CF₄, SF₆, or a combination of these gases, can be employed to selectively remove the first insulating layer 130. These etchants are highly selective to silicon nitride (SiN) over both polysilicon and SiC. As a result, the first insulating layer 130 can be efficiently removed without etching or damaging the gate electrode 340, oxide layer 210, and SiC material of the underlying source regions 110 and doped regions 118. This selective etching ensures that the gate structure, consisting of the gate electrode 340 and the oxide layer 210, remains intact, while the first insulating layer 130 is completely eliminated, preparing the semiconductor structure 100 for subsequent processing steps.

In this embodiment, after the removal of the first insulating layer 130, a first (protruding) portion 340a of the gate electrode 340 extends or protrudes vertically above a horizontal plane (x-direction) defined by the substantially coplanar upper surfaces of the source regions 110 and doped regions 118. Stated differently, the protruding first portion 340a extends vertically above the trench 132. A second portion 340b of the gate electrode 340 is positioned above the oxide layer 210 substantially filling the trench 132. In an embodiment, a height or vertical thickness (y-direction) of the protruding first portion 340a of the gate electrode 340 can vary between approximately 0.1 μm and 2.0 μm, and ranges therebetween.

FIG. 6 is a cross-sectional view of the semiconductor structure 100 after forming a second insulating layer 602 above upper surfaces of the gate electrode 340, source regions 110, and doped regions 118, according to an embodiment of the present disclosure. It should be noted that the description of FIG. 6 can refer to components shown in FIG. 1, FIG. 2, FIG. 3, FIG. 4, and FIG. 5.

Following the removal of the first insulating layer 130, an intermetal dielectric (IMD) material, typically an insulating material such as silicon dioxide (SiO₂) or a low-k dielectric, can be deposited over the entire semiconductor structure 100. Typically, the deposition process can be performed using CVD or another suitable deposition technique that can ensure uniform coverage. As depicted in FIG. 6, the deposited second insulating layer 602 tends to accumulate more around the edges of features such as the gate electrode 340, which has vertical sidewalls. This results in the second insulating layer 602 having a semi-circular or dome-like shape, particularly over the gate electrode 340, as depicted in the figure. In an embodiment, the second insulating layer 602 may have a thickness of approximately 0.1 μm to approximately 2.0 μm, and ranges therebetween.

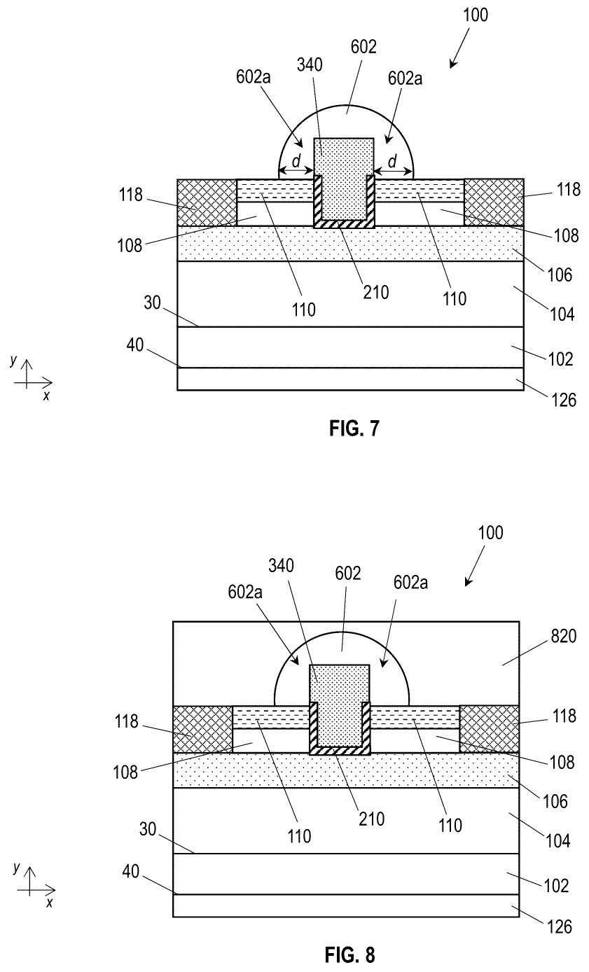

FIG. 7 is a cross-sectional view of the semiconductor structure 100 after etching the second insulating layer 602, according to an embodiment of the present disclosure. It should be noted that the description of FIG. 7 can refer to components shown in FIG. 1, FIG. 2, FIG. 3, FIG. 4, FIG. 5, and FIG. 6.

In this embodiment, a blanket etching process can be performed to pattern the insulating material forming the second insulating layer 602 in a self-aligned manner. During the self-aligned etching step, the gate region, defined by the previously formed gate electrode 340, serves as a natural boundary for the etching process. The etching process selectively removes the second insulating layer 602 from areas above the doped regions 118 and partially from areas above the source regions 110, while leaving the insulating material intact above the gate electrode 340. As depicted in the figure, the remaining portions of the second insulating layer 602 surround the protruding first portion 340a of the gate electrode 340. Typically, the etching process can be performed using RIE, which provides high selectivity for the insulating material over the underlying structures. This ensures that the protruding first portion 340a of gate electrode 340 remains covered by the second insulating layer 602, while the insulating material is effectively removed from the regions where it is not needed.

In one or more embodiments, the remaining portions of the second insulating layer 602, positioned on opposite sides of the gate electrode 340, may function as sidewall spacers 602a. Sidewall spacers 602a may help define the lateral extent of the gate region and provide electrical isolation between the gate electrode 340 and the surrounding regions, such as the source regions 110. The precise thickness and positioning of the sidewall spacers 602a can be controlled through the etching process and are important for the overall performance and reliability of the semiconductor structure 100.

In an embodiment, sidewall spacers 602a are disposed on both sides of the gate electrode 340. As shown in the figure, sidewall spacers 602a can be positioned with approximately the same distance d between an edge of the protruding first portion 340a of the gate electrode 340 and an exposed portion of the source region 110. The uniform distance d may ensure symmetrical isolation around the gate electrode 340, contributing to the consistent performance of the semiconductor structure 100. In an embodiment, the distance d between the protruding first portion 340a of the gate electrode 340 and the exposed portion of the source region 110 can be equivalent to a width or horizontal thickness of the sidewall spacers 602a. The distance d may vary between approximately 0.1 μm to approximately 2 μm. In an embodiment, the distance d is equivalent to a width or horizontal thickness (x-direction) of the sidewall spacers 602a positioned along opposite sidewalls of the protruding first portion 340a of the gate electrode 340. In an embodiment, a portion of spacer material remaining on top of an upper surface of the protruding first portion 340a of the gate electrode 340 exhibits the semi-circular or dome-like shape.

FIG. 8 is a cross-sectional view of the semiconductor structure 100 after forming a top metal layer 820, according to an embodiment of the present disclosure. It should be noted that the description of FIG. 8 can refer to components shown in FIG. 1, FIG. 2, FIG. 3, FIG. 4, FIG. 5, FIG. 6, and FIG. 7.

In this embodiment, top metal layer 820 can be formed above second insulating layer 602 and above exposed portions of source region 110 and doped region 118. The top metal layer 820 provides a source terminal or source electrode (ohmic contact) that electrically contacts source region 110 and doped region 118.

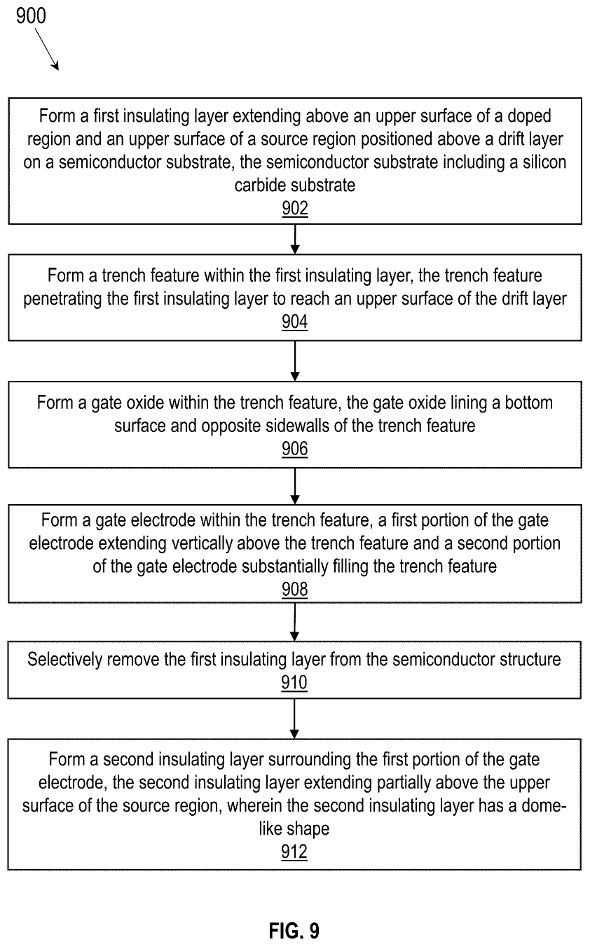

FIG. 9 is a flowchart 900 depicting operational steps for the fabrication of the semiconductor structure 100, according to an embodiment of the present disclosure. It should be noted that the description of FIG. 8 can refer to components shown in FIG. 1, FIG. 2, FIG. 3, FIG. 4, FIG. 5, FIG. 6, FIG. 7, and FIG. 8.

The fabrication process starts at step 902 by forming a first insulating layer that extends above an upper surface of a doped region and an upper surface of a source region positioned above a drift layer on a semiconductor substrate. In an embodiment, the upper surface of the doped region is coplanar with the upper surface of the source region. In an embodiment, the semiconductor substrate includes a silicon carbide substrate. In an embodiment, the first insulating layer includes a silicon nitride layer.

The process continues at step 904 by forming a trench feature within the first insulating layer. In an embodiment, the trench feature penetrates the first insulating layer to reach an upper surface of the drift layer.

The process continues at step 906 by forming a gate oxide within the trench feature. In an embodiment, the gate oxide lines a bottom surface and opposite sidewalls of the trench feature.

The process continues at step 908 by forming a gate electrode within the trench feature. In an embodiment, a first portion of the gate electrode extends vertically above the trench feature, while a second portion of the gate electrode substantially fills the trench feature. In an embodiment the process of forming the gate electrode within the trench feature further includes the steps of depositing a conductive material within the trench feature in contact with the gate oxide with the deposited conductive material extending above an upper surface of the first insulating layer, and selectively etching the conductive material from the upper surface of the first insulating layer. In an embodiment, a thickness of the first portion of the gate electrode extending above the trench is more than 0.1 μm and less than 2.0 μm.

The process continues at step 910 by selectively removing the first insulating layer from the semiconductor structure. In an embodiment, selectively removing the first insulating layer from the semiconductor structure exposes the first portion of the gate electrode extending vertically above the trench.

Finally, at step 912, a second insulating layer is formed surrounding the first portion of the gate electrode. In an embodiment, the second insulating layer extends partially above the upper surface of the source region. In an embodiment, the second insulating layer has a dome-like shape. In an embodiment, the second insulating layer includes a silicon oxide layer. In an embodiment, the process of forming the second insulation layer further includes the steps of depositing an insulating material above the exposed first portion of the gate electrode, with vertical sidewalls of the gate electrode causing the deposited insulating material to accumulate around edges of the first portion of the gate electrode to form the dome-like shape, and etching the second insulating layer from the upper surface of the doped region and partially from the upper surface of the source region. In an embodiment, portions the second insulating layer disposed on opposite sidewalls of the first portion of the gate electrode provide sidewall spacers for electrically isolating the first portion of the gate electrode, with the sidewall spacers being positioned within a same distance from an edge of the first portion of the gate electrode and an exposed portion of the source region. In an embodiment, the same distance is more than 0.1 μm and less than 2.0 μm.

### EXAMPLES

Example 1. A method of forming a semiconductor structure comprising:
   forming a first insulating layer extending above an upper surface of a doped region and an upper surface of a source region positioned above a drift layer on a semiconductor substrate, wherein the semiconductor substrate comprises a silicon carbide substrate;
   forming a trench feature within the first insulating layer, the trench feature penetrating the first insulating layer to reach an upper surface of the drift layer;
   forming a gate oxide within the trench feature, the gate oxide lining a bottom surface and opposite sidewalls of the trench feature;
   forming a gate electrode within the trench feature, a first portion of the gate electrode extending vertically above the trench feature, a second portion of the gate electrode filling the trench feature;
   selectively removing the first insulating layer from the semiconductor structure; and forming a second insulating layer surrounding the first portion of the gate electrode, the second insulating layer extending partially above the upper surface of the source region, wherein the second insulating layer has a dome-like shape.
Example 2. The method according to Example 1, wherein the gate electrode comprises a conductive material, and wherein forming the gate electrode within the trench feature further comprises:
   depositing the conductive material within the trench feature in contact with the gate oxide, the deposited conductive material extending above an upper surface of the first insulating layer; and
   selectively etching the conductive material from the upper surface of the first insulating layer.
Example 3. The method according to Example 1, wherein a thickness of the first portion of the gate electrode is more than 0.1 μm and less than 2.0 μm.
Example 4. The method according to Example 1, wherein selectively removing the first insulating layer from the semiconductor structure exposes the first portion of the gate electrode extending vertically above the trench.
Example 5. The method according to Example 4, wherein forming the second insulating layer further comprises:
   depositing an insulating material above the exposed first portion of the gate electrode, wherein vertical sidewalls of the gate electrode causes the deposited insulating material to accumulate around edges of the first portion of the gate electrode to form the dome-like shape; and
   etching the second insulating layer from the upper surface of the doped region and partially from the upper surface of the source region.
Example 6. The method according to Example 1, wherein the first insulating layer comprises a silicon nitride layer, and the second insulating layer comprises a silicon oxide layer.
Example 7. The method according to Example 1, wherein portions the second insulating layer disposed on opposite sidewalls of the first portion of the gate electrode provide sidewall spacers for electrically isolating the first portion of the gate electrode.
Example 8. The method according to Example 7, wherein the sidewall spacers are positioned within a same distance from an edge of the first portion of the gate electrode and an exposed portion of the source region.
Example 9. The method according to Example 8, wherein the same distance is more than 0.1 μm and less than 2.0 μm.
Example 10. The method according to Example 1, further comprising:
   forming the drift layer above the semiconductor substrate, the drift layer and the semiconductor substrate including a first conductivity type;
   forming a junction field-effect transistor (JFET) region of the first conductivity type above the drift layer;
   forming a base region of a second conductivity type above the JFET region, the base region providing a channel region for the semiconductor structure;
   forming the source region above the base region, wherein the source region comprises the first conductivity type;
   forming the doped region above the JFET region and adjacent to the source region and the base region, the doped region comprising the second conductivity type;
   forming a bottom metal layer above the semiconductor substrate; and
   forming a top metal layer above the second insulating layer, the doped region and uncovered portions of the source region.
Example 11. A method of forming a semiconductor structure comprising:
   forming a drift layer above a semiconductor substrate, the drift layer and the semiconductor substrate comprising a first conductivity type, the semiconductor substrate comprising a silicon carbide substrate;
   forming a base region of a second conductivity type above the drift layer, the base region providing a channel region for the semiconductor structure;
   forming a source region of the first conductivity type above the base region;
   forming a doped region of the second conductivity type adjacent to the base region and the source region;
   forming a first insulating layer above the doped region and the source region;
   forming a trench feature within the first insulating layer, the trench feature penetrating the first insulating layer to reach an upper surface of the drift layer;
   forming a gate oxide within the trench feature, the gate oxide lining a bottom surface and opposite sidewalls of the trench feature;
   forming a gate electrode within the trench feature, a first portion of the gate electrode extends vertically above the trench feature, a second portion of the gate electrode filling the trench feature;
   selectively removing the first insulating layer from the semiconductor structure; and
   forming sidewall spacers on opposite sides of the first portion of the gate electrode, wherein a portion of a spacer material forming the sidewall spacers remains above the first portion of the gate electrode providing a dome-like shape, the sidewall spacers extending partially above the upper surface of the source region.
Example 12. The method according to Example 11, wherein a thickness of the first portion of the gate electrode is more than 0.1 μm and less than 2.0 μm.
Example 13. The method according to Example 11, wherein the first insulating layer comprises a silicon nitride layer.
Example 14. The method according to Example 11, wherein the sidewall spacers comprise a silicon oxide layer.
Example 15. The method according to Example 11, wherein the sidewall spacers electrically isolate the first portion of the gate electrode, with portions of the sidewall spacer material accumulating on edges of the first portion of the gate structure to form the dome-like shape.
Example 16. The method according to Example 15, wherein a width of the sidewall spacers is more than 0.1 μm and less than 2.0 μm.
Example 17. The method according to Example 1, further comprising:
   forming a junction field-effect transistor (JFET) region of the first conductivity type above the drift layer;
   forming a bottom metal layer above the semiconductor substrate; and
   forming a top metal layer above the second insulating layer, the doped region and uncovered portions of the source region.
Example 18. A semiconductor structure comprising:
   a drift layer disposed above a semiconductor substrate, the drift layer and the semiconductor substrate comprising a first conductivity type, wherein the semiconductor substrate comprises a silicon carbide substrate;
   a gate electrode within a trench feature positioned above the drift layer, the gate electrode including a first portion and a second portion, wherein the first portion of the gate electrode extends above the trench feature and the second portion of the gate electrode fills the trench feature;
   a source region of the first conductivity type adjacent to the second portion of the gate electrode;
   a doped region of a second conductivity type adjacent to the source region, wherein an upper surface of the doped region is coplanar with an upper surface of the source region; and
   an insulating layer surrounding the first portion of the gate electrode, the insulating layer partially covering the upper surface of the source region, the insulating layer comprising a dome-like shape.
Example 19. The semiconductor structure according to Example 18,
   wherein a thickness of the first portion of the gate electrode is more than 0.1 μm and less than 2.0 μm, and
   wherein a thickness of the insulating layer from a sidewall of the first portion of the gate electrode to an uncovered upper surface of the source region is more than 0.1 μm and less than 2.0 μm.
Example 20. The semiconductor according to Example 18, further comprising:
   a JFET region of the first conductivity type above the drift layer, the JFET region positioned adjacent to the second portion of the gate electrode;
   a base region of the second conductivity type, the base region positioned adjacent to the second portion of the gate electrode on a first side and adjacent to the doped region on a second side opposing the first side, the base region located below the source region, wherein the base region provides a channel region for the semiconductor structure;
   a gate oxide lining the second portion of the gate electrode;
   a bottom metal layer positioned below the semiconductor substrate; and
   a top metal layer position above the insulating layer, the doped region and an uncovered upper surface of the source region.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of forming a semiconductor structure comprising:
forming a first insulating layer extending above an upper surface of a doped region and an upper surface of a source region positioned above a drift layer on a semiconductor substrate, wherein the semiconductor substrate comprises a silicon carbide substrate;
forming a trench feature within the first insulating layer, the trench feature penetrating the first insulating layer to reach an upper surface of the drift layer;
forming a gate oxide within the trench feature, the gate oxide lining a bottom surface and opposite sidewalls of the trench feature;
forming a gate electrode within the trench feature, a first portion of the gate electrode extending vertically above the trench feature, a second portion of the gate electrode filling the trench feature;
selectively removing the first insulating layer from the semiconductor structure; and
forming a second insulating layer surrounding the first portion of the gate electrode, the second insulating layer extending partially above the upper surface of the source region, wherein the second insulating layer has a dome-like shape.

2. The method according to claim 1, wherein the gate electrode comprises a conductive material, and wherein forming the gate electrode within the trench feature further comprises:
depositing the conductive material within the trench feature in contact with the gate oxide, the deposited conductive material extending above an upper surface of the first insulating layer; and
selectively etching the conductive material from the upper surface of the first insulating layer.

3. The method according to claim 1, wherein a thickness of the first portion of the gate electrode is more than 0.1 μm and less than 2.0 μm.

4. The method according to claim 1, wherein selectively removing the first insulating layer from the semiconductor structure exposes the first portion of the gate electrode extending vertically above the trench feature.

5. The method according to claim 4, wherein forming the second insulating layer further comprises:
depositing an insulating material above the exposed first portion of the gate electrode, wherein vertical sidewalls of the gate electrode causes the deposited insulating material to accumulate around edges of the first portion of the gate electrode to form the dome-like shape; and
etching the second insulating layer from the upper surface of the doped region and partially from the upper surface of the source region.

6. The method according to claim 1, wherein the first insulating layer comprises a silicon nitride layer, and the second insulating layer comprises a silicon oxide layer.

7. The method according to claim 1, wherein portions the second insulating layer disposed on opposite sidewalls of the first portion of the gate electrode provide sidewall spacers for electrically isolating the first portion of the gate electrode.

8. The method according to claim 7, wherein the sidewall spacers are positioned within a same distance from an edge of the first portion of the gate electrode and an exposed portion of the source region.

9. The method according to claim 8, wherein the same distance is more than 0.1 μm and less than 2.0 μm.

10. The method according to claim 1, further comprising:
forming the drift layer above the semiconductor substrate, the drift layer and the semiconductor substrate including a first conductivity type;
forming a junction field-effect transistor (JFET) region of the first conductivity type above the drift layer;
forming a base region of a second conductivity type above the JFET region, the base region providing a channel region for the semiconductor structure;
forming the source region above the base region, wherein the source region comprises the first conductivity type;
forming the doped region above the JFET region and adjacent to the source region and the base region, the doped region comprising the second conductivity type;
forming a bottom metal layer above the semiconductor substrate; and
forming a top metal layer above the second insulating layer, the doped region and uncovered portions of the source region.

11. A method of forming a semiconductor structure comprising:
forming a drift layer above a semiconductor substrate, the drift layer and the semiconductor substrate comprising a first conductivity type, the semiconductor substrate comprising a silicon carbide substrate;
forming a base region of a second conductivity type above the drift layer, the base region providing a channel region for the semiconductor structure;
forming a source region of the first conductivity type above the base region;
forming a doped region of the second conductivity type adjacent to the base region and the source region;
forming a first insulating layer above the doped region and the source region;
forming a trench feature within the first insulating layer, the trench feature penetrating the first insulating layer to reach an upper surface of the drift layer;
forming a gate oxide within the trench feature, the gate oxide lining a bottom surface and opposite sidewalls of the trench feature;
forming a gate electrode within the trench feature, a first portion of the gate electrode extends vertically above the trench feature, a second portion of the gate electrode filling the trench feature;
selectively removing the first insulating layer from the semiconductor structure; and
forming sidewall spacers on opposite sides of the first portion of the gate electrode, wherein a portion of a spacer material forming the sidewall spacers remains above the first portion of the gate electrode providing a dome-like shape, the sidewall spacers extending partially above the upper surface of the source region.

12. The method according to claim 11, wherein a thickness of the first portion of the gate electrode is more than 0.1 mm and less than 2.0 mm.

13. The method according to claim 11, wherein the first insulating layer comprises a silicon nitride layer.

14. The method according to claim 11, wherein the sidewall spacers comprise a silicon oxide layer.

15. The method according to claim 11, wherein the sidewall spacers electrically isolate the first portion of the gate electrode, with portions of the sidewall spacer material accumulating on edges of the first portion of the gate electrode to form the dome-like shape.

16. The method according to claim 15, wherein a width of the sidewall spacers is more than 0.1 μm and less than 2.0 μm.

17. The method according to claim 11, further comprising:
forming a junction field-effect transistor (JFET) region of the first conductivity type above the drift layer;
forming a bottom metal layer above the semiconductor substrate; and
forming a top metal layer above the second insulating layer, the doped region and uncovered portions of the source region.

18. A semiconductor structure comprising:
a drift layer disposed above a semiconductor substrate, the drift layer and the semiconductor substrate comprising a first conductivity type, wherein the semiconductor substrate comprises a silicon carbide substrate;
a gate electrode within a trench feature positioned above the drift layer, the gate electrode including a first portion and a second portion, wherein the first portion of the gate electrode extends above the trench feature and the second portion of the gate electrode fills the trench feature;
a source region of the first conductivity type adjacent to the second portion of the gate electrode;
a doped region of a second conductivity type adjacent to the source region, wherein an upper surface of the doped region is coplanar with an upper surface of the source region; and
an insulating layer surrounding the first portion of the gate electrode, the insulating layer partially covering the upper surface of the source region, the insulating layer comprising a dome-like shape.

19. The semiconductor structure according to claim 18,
wherein a thickness of the first portion of the gate electrode is more than 0.1 μm and less than 2.0 μm, and
wherein a thickness of the insulating layer from a sidewall of the first portion of the gate electrode to an uncovered upper surface of the source region is more than 0.1 μm and less than 2.0 μm.

20. The semiconductor structure according to claim 18, further comprising:
a JFET region of the first conductivity type above the drift layer, the JFET region positioned adjacent to the second portion of the gate electrode;
a base region of the second conductivity type, the base region positioned adjacent to the second portion of the gate electrode on a first side and adjacent to the doped region on a second side opposing the first side, the base region located below the source region, wherein the base region provides a channel region for the semiconductor structure;
a gate oxide lining the second portion of the gate electrode;
a bottom metal layer positioned below the semiconductor substrate; and
a top metal layer position above the insulating layer, the doped region and an uncovered upper surface of the source region.
